(19) United States
(12) Patent Application Publication
(10) Pub. No.: US 2016/0322601 A1
(43) Pub. Date: Nov. 3, 2016

(54) FLEXIBLE DISPLAY APPARATUS AND METHOD OF MANUFACTURING THE SAME

(71) Applicant: SAMSUNG DISPLAY CO., LTD., Yongin-si (KR)

(72) Inventor: Kunwon Lee, Yongin-si (KR)

(21) Appl. No.: 14/928,620

(22) Filed: Oct. 30, 2015

(30) Foreign Application Priority Data
Apr. 30, 2015 (KR) 10-2015-0062024

(51) Int. Cl. H01L 51/52; H01L 51/56; H01L 27/32

(52) U.S. Cl. CPC H01L 51/5256; H01L 27/3248; H01L 51/56; H01L 2251/5338

(57) ABSTRACT

A flexible display apparatus includes a flexible substrate, a display unit on the flexible substrate, a first encapsulation unit covering the display unit, defining a first through portion therethrough, and including a first organic layer, and a first inorganic layer on the first organic layer, and a first material in the first through portion that is different from a material of the first organic layer.

### CROSS-REFERENCE TO RELATED APPLICATION

This application claims priority to, and the benefit of, Korean Patent Application No. 10-2015-0062024, filed on Apr. 30, 2015, in the Korean Intellectual Property Office, the disclosure of which is incorporated herein in its entirety by reference.

### BACKGROUND

1. Field

One or more exemplary embodiments relate to a flexible display apparatus and a method of manufacturing the same, and more particularly, to a flexible display apparatus having improved flexibility and a method of manufacturing the same.

2. Description of the Related Art

A display panel is a device configured to display an image signal. Examples of the display panel include a television, a digital camera, a smartphone, a laptop computer, a tablet personal computer, a camcorder, a video camera, and the like, and the display panel is a concept including any device that is configured to display an image corresponding to an signal input from outside of the display panel.

Flexible display panels that are easy to carry and that are applicable to devices having various shapes have recently been developed. In particular, a flexible display panel including organic light-emitting diodes is one of the most powerful display apparatuses.

Meanwhile, a flexible display panel is manufactured by forming a display unit on a flexible substrate, and then forming an encapsulation unit on the display unit. The encapsulation unit encapsulates the display unit, which would otherwise be vulnerable to damage caused by moisture and oxygen, thereby improving product reliability.

However, according to a conventional flexible display apparatus, when a flexible panel is bent, a curvature radius of the flexible display apparatus is restricted by stress applied to an encapsulation unit on the flexible panel, thereby limiting the degree to which the flexible panel may be bent.

### SUMMARY

One or more exemplary embodiments include a flexible display apparatus having improved flexibility and a method of manufacturing the same.

Additional aspects will be set forth in part in the description which follows and, in part, will be apparent from the description, or may be learned by practice of the presented embodiments.

According to one or more exemplary embodiments, a flexible display apparatus includes a flexible substrate, a display unit on the flexible substrate, a first encapsulation unit covering the display unit, defining a first through portion therethrough, and including a first organic layer, and a first inorganic layer on the first organic layer, and a first material in the first through portion that is different from a material of the first organic layer.

The first inorganic layer may include a material that is the same as the first material.

The first material may include a metal having an elongation of about 5% or higher.

The display unit may include a thin film transistor, and an organic light-emitting device including a pixel electrode electrically connected to the thin film transistor, an intermediate layer including an emission layer on the pixel electrode, and an opposite electrode on the intermediate layer and facing the pixel electrode, and the first material may contact the opposite electrode.

The flexible substrate may have a bending area at which the flexible substrate is configured to be bent, and a flat area adjacent the bending area, and the first through portion may be at the bending area.

The first through portion may extend along a bending axis direction of the bending area.

The flexible display apparatus may further include a second encapsulation unit on the first encapsulation unit, defining a second through portion therethrough, and including a second organic layer, and a second inorganic layer on the second organic layer, and a second material in the second through portion that is different from a material of the second organic layer.

The second inorganic layer may include a material that is the same as the second material.

The second material may include a metal having an elongation of about 5% or higher.

The first material may include a first metal, and the second material may include a second metal having a higher elongation than that of the first metal.

The second material may contact the first inorganic layer.

The flexible substrate may have a bending area at which the flexible substrate is configured to be bent, and a flat area adjacent the bending area, and the first through portion and the second through portion may be at the bending area.

The first through portion and the second through portion may extend along a bending axis direction of the bending area.

The flexible display apparatus may further include a third inorganic layer between the display unit and the first encapsulation unit, and the first material may contact the third inorganic layer.

According to one or more exemplary embodiments, a method of manufacturing a flexible display apparatus includes forming a display unit on a flexible substrate, forming a first encapsulation unit covering the display unit by forming a first organic layer on the display unit, and forming a first inorganic layer on the first organic layer, forming a first through portion through the first encapsulation unit, and filling a first material in the first through portion, wherein the first organic layer includes a material that is different from the first material.

The first material may include a same material as the first inorganic layer, or a metal having an elongation of about 5% or higher.

The forming of the first through portion may include etching a portion of the first encapsulation unit.

The forming of a first through portion may include using a patterned mask.

These general and specific embodiments may be implemented by using a system, a method, a computer program, or a combination of the system, the method, and the computer program.

### BRIEF DESCRIPTION OF THE DRAWINGS

These and/or other aspects will become apparent and more readily appreciated from the following description of the exemplary embodiments, taken in conjunction with the accompanying drawings in which:

FIG. 1 is a schematic cross-sectional view illustrating a flexible display apparatus according to an exemplary embodiment of the inventive concept;

FIG. 2 is a detailed cross-sectional view illustrating a display unit and an encapsulation unit of the flexible display apparatus of FIG. 1;

FIG. 3 is a schematic cross-sectional view illustrating a flexible display apparatus according to an exemplary embodiment of the inventive concept;

FIG. 4 is a schematic cross-sectional view illustrating the flexible display apparatus of FIG. 3;

FIG. 5 is a schematic cross-sectional view illustrating a flexible display apparatus according to an exemplary embodiment of the inventive concept;

FIG. 6 is a schematic cross-sectional view illustrating a bending area and a flat area of a flexible display apparatus according to an exemplary embodiment of the inventive concept;

FIG. 7 is a schematic plan view illustrating an organic layer included in an encapsulation unit of a flexible display apparatus according to an exemplary embodiment of the inventive concept; and

FIG. 8 is a schematic plan view illustrating an organic layer included in an encapsulation unit of a flexible display apparatus according to an exemplary embodiment of the inventive concept.

### DETAILED DESCRIPTION

Features of the inventive concept and methods of accomplishing the same may be understood more readily by reference to the following detailed description of embodiments and the accompanying drawings. The inventive concept may, however, be embodied in many different forms and should not be construed as being limited to the embodiments set forth herein. Hereinafter, example embodiments will be described in more detail with reference to the accompanying drawings, in which like reference numbers refer to like elements throughout. The present invention, however, may be embodied in various different forms, and should not be construed as being limited to only the illustrated embodiments herein. Rather, these embodiments are provided as examples so that this disclosure will be thorough and complete, and will fully convey the aspects and features of the present invention to those skilled in the art. Accordingly, processes, elements, and techniques that are not necessary to those having ordinary skill in the art for a complete understanding of the aspects and features of the present invention may not be described. Unless otherwise noted, like reference numerals denote like elements throughout the attached drawings and the written description, and thus, descriptions thereof will not be repeated. In the drawings, the relative sizes of elements, layers, and regions may be exaggerated for clarity.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present invention.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that when an element or layer is referred to as being “on,” “connected to,” or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments only and is not intended to be limiting of the present invention. As used herein, the singular forms “a,” “an,” and “the” are intended to include the plural forms as well, unless the context clearly indicates otherwise. It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the term “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present invention refers to “one or more embodiments of the present invention.” As used herein, the terms “use,” “using,” and “used” may be considered synonymous with the terms “utilize,” “utilizing,” and “utilized,” respectively. Also, the term “exemplary” is intended to refer to an example or illustration.

The electronic or electric devices and/or any other relevant devices or components according to embodiments of the present invention described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the exemplary embodiments of the present invention.

In the exemplary embodiments below, an x-axis, a y-axis, and a z-axis are not limited to three axes on a rectangular coordinates system but may be construed as including these axes. For example, an-x axis, a y-axis, and a z-axis may be at right angles or not may also indicate different directions from one another, which are not at right angles.

When an exemplary embodiment is implementable in another manner, a predetermined process order may be different from a described one. For example, two processes that are consecutively described may be substantially simultaneously performed or may be performed in an opposite order to the described order.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

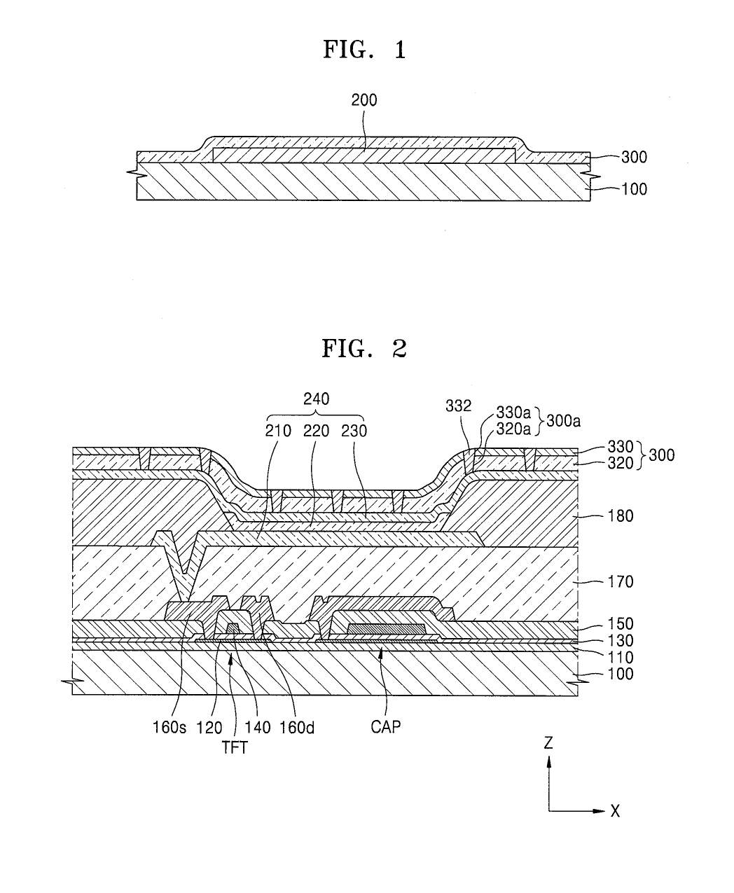

FIG. 1 is a schematic cross-sectional view illustrating a flexible display apparatus according to an exemplary embodiment of the inventive concept, and FIG. 2 is a detailed cross-sectional view illustrating a display unit and an encapsulation unit of the flexible display apparatus of FIG. 1.

Referring to FIGS. 1 and 2, the flexible display apparatus according to an exemplary embodiment includes a flexible substrate 100, a display unit 200 on the flexible substrate 100, a first encapsulation unit 300 covering the display unit 200, and a first through portion 300a passing through the first encapsulation unit 300.

The substrate 100 may be formed of various materials such as glass, a metal, or a plastic material such as polyethylene terephthalate (PET), polyethylene naphthalate (PEN), polyimide, or the like. The substrate 100 may have a display area in which a plurality of pixels are arranged, and a peripheral area surrounding the display area.

The flexible substrate 100 has flexibility, excellent heat resistance, and durability, and may be formed of a plastic material that may be formed to a curved surface, such as polyethylene ether phthalate, polyethylene naphthalate, polycarbonate, polyarylate, polyetherimide, polyethersulfone, polyimide, or the like. However, the material of the flexible substrate 100 is not limited thereto, and may also be a metal or other various materials.

The display unit 200 is on the flexible substrate 100, and includes a plurality of pixels PX. For example, the display unit 200 may be an organic light-emitting display layer including a plurality of thin film transistors (TFTs), and pixel electrodes connected to the TFTs. Alternatively, the display unit 200 may be a liquid crystal display layer. Embodiments in which the display unit 200 is an organic light-emitting display layer will be described below.

Each of the pixels PX includes a TFT and an organic light-emitting device 240, and the TFT includes a semiconductor layer 120 including amorphous silicon, polycrystalline silicon, or an organic semiconductor material, a gate electrode 140, and a source electrode 160s and a drain electrode 160d. Also, the organic light-emitting device 240 includes a pixel electrode 210, an intermediate layer 220 including an emission layer (EML) on the pixel electrode 210, and an opposite electrode 230.

The first encapsulation unit 300 is on the display unit 200, and may be located over the entire surface of the flexible substrate 100 to cover the display unit 200. An edge of the first encapsulation unit 300 may contact the flexible substrate 100 to thereby protect the display unit 200, which is otherwise vulnerable to damage caused by oxygen and moisture from outside the display apparatus.

Referring to FIG. 2, a buffer layer 110 formed of a silicon oxide, a silicon nitride, or the like may be located on the flexible substrate 100 to planarize a surface of the flexible substrate 100, or to prevent penetration of impurities into the semiconductor layer 120 of the TFT. The semiconductor layer 120 may be on the buffer layer 110.

The gate electrode 140 is on the semiconductor layer 120, and the source electrode 160s and the drain electrode 160d are configured to be electrically connected to each other according to a signal applied to the gate electrode 140. The gate electrode 140 may have a single layer structure, or may have a multilayer structure including, for example, at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). A choice of the materials may take into account adhesive properties with respect to adjacent layers, surface planarization of stacked layers, and processability.

Here, to provide insulation properties between the semiconductor layer 120 and the gate electrode 140, a gate insulation layer 130 formed of a silicon oxide, a silicon nitride, and/or the like may be between the semiconductor layer 120 and the gate electrode 140.

An interlayer insulation layer 150 may be on the gate electrode 140, and may have a single layer structure or a multilayer structure formed of a material such as a silicon oxide or a silicon nitride.

The source electrode 160s and the drain electrode 160d are on the interlayer insulation layer 150, and are electrically connected to the semiconductor layer 120 through respective contact holes formed in the interlayer insulation layer 150 and in the gate insulation layer 130. The source electrode 160s and the drain electrode 160d may have a single layer structure, or may have a multilayer structure formed of, for example, at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). A choice of the materials may take into account conductivity or the like.

To protect the TFT having the above-described structure, a protection layer may additionally be on the TFT to cover the TFT, and may be formed of, for example, an inorganic material, such as a silicon oxide, a silicon nitride, and/or a silicon oxynitride.

A first insulation layer 170 may be on the flexible substrate 100, and may serve as a planarization layer or a protection layer. The first insulation layer 170 generally planarizes an upper surface of the TFT, and protects the TFT and various elements when an organic light-emitting device is on the TFT. The first insulation layer 170 may be formed of, for example, an acrylic organic material or benzocyclobutene (BCB). As illustrated in FIG. 2, the buffer layer 110, the gate insulation layer 130, the interlayer insulation layer 150, and the first insulation layer 170 may be formed over the entire surface of the flexible substrate 100.

A second insulation layer 180 may be on the TFT, and may be a pixel defining layer. The second insulation layer 180 may be on the first insulation layer 170 described above, and may have an opening to define a pixel area on the flexible substrate 100. The second insulation layer 180 may include, for example, an organic insulation layer. Examples of the organic insulation layer may include an acrylic polymer, such as polymethyl methacrylate (PMMA), polystyrene (PS), a polymer derivative having a phenol group, an imide-based polymer, an arylether-based polymer, an amide-based polymer, a fluorine-based polymer, a p-xylene-based polymer, a vinyl alcohol-based polymer, and/or a mixture thereof.

The organic light-emitting device 240 may be on the second insulation layer 180, and may include the pixel electrode 210, the intermediate layer 220 including an EML, and the opposite electrode 230.

The pixel electrode 210 may include a transparent or semi-transparent electrode or a reflective electrode. When the pixel electrode 210 includes a transparent or semi-transparent electrode, the pixel electrode 210 may be formed of, for example, ITO, IZO, ZnO, In₂O₃, IGO, and/or AZO. When the pixel electrode 210 includes a reflective electrode, the pixel electrode 210 may have a reflective film formed of, for example, Ag, Mg, Al, Pt, Pd, Au, Ni, Nd, Ir, Cr, and any combinations thereof, and a layer formed of ITO, IZO, ZnO, In₂O₃, IGO, and/or AZO. However, the present inventive concept is not limited thereto, and the pixel electrode 210 may be formed of various materials. Also, the structure of the pixel electrode 210 may vary (e.g., as a single layer or as a multilayer structure).

The intermediate layer 220 may be arranged in the pixel area that is defined by the second insulation layer 180. The intermediate layer 220 may include an EML that is configured to emit light according to an electric signal, a hole injection layer (HIL) between the EML and the pixel electrode 210, a hole transport layer (HTL), an electron transport layer (ETL) between the EML and the opposite electrode 230, and/or an electron injection layer (EIL), the layers being stacked in a single or combined structure. However, the intermediate layer 220 is not limited thereto and may have various structures.

The intermediate layer 220 may be formed of a low-molecular weight organic material, or may be formed of a polymer organic material. When the intermediate layer 220 is formed of a low-molecular weight organic material, an HTL, an HIL, an ETL, and an EIL may be stacked with respect to the EML. In addition, other various layers may be stacked in other embodiments. The intermediate layer 220 may be formed of, as an organic material, various materials, such as copper phthalocyanine (CuPc), N,N′-Di(naphthalene-1-yl)-N,N′-diphenyl-benzidine (NPB), and tris-8-hydroxyquinoline aluminum (Alq3).

When the intermediate layer 220 includes a polymer organic material, an HTL may be provided in addition to the intermediate layer 220. The HTL may use poly-(2,4)-ethylene-dihydroxy thiophene (PEDOT) or polyaniline (PANI). The intermediate layer 220 may use, as an organic material, polymer organic materials, such as a poly (p-phenylene vinylene) (PPV)-based polymer material and a polyfluorene-based polymer material. Also, an inorganic material may be provided between the intermediate layer 220 and the pixel electrode 210, or between the intermediate layer 220 and the opposite electrode 230.

The HTL, the HIL, the ETL, and the EIL may be formed over the entire surface of the flexible substrate 100, and may be formed as a single unit with the flexible substrate 100. The EML may be formed for each pixel by using an inkjet printing operation. Also, the HTL, the HIL, the ETL, and the EIL may be located inside a step portion.

The opposite electrode 230 facing the pixel electrode 210, while covering the intermediate layer 220 including the EML, may be arranged on the entire surface of the substrate 100. The opposite electrode 230 may include a transparent or semi-transparent electrode, or may include a reflective electrode.

When the opposite electrode 230 includes a transparent or semi-transparent electrode, the opposite electrode 230 may have a layer formed of a metal having a low work function, such as Li, Ca, LiF/Ca, LiF/AI, Al, Ag, Mg, and/or a compound thereof, and may also have a transparent or semi-transparent conductive layer, such as ITO, IZO, ZnO, and/or In₂O₃. When the opposite electrode 230 includes a reflective electrode, the opposite electrode 230 may have a layer formed of Li, Ca, LiF/Ca, LiF/AI, Al, Ag, Mg, and/or a compound thereof. However, the structure and material of the opposite electrode 230 are not limited thereto, and various modifications thereof may be made.

The first encapsulation unit 300 may be on the flexible substrate 100 and may cover the display unit 200. The first encapsulation unit 300 may have a multilayer structure including a first organic layer 320 and a first inorganic layer 330. FIG. 2 illustrates that the first organic layer 320 is on the opposite electrode 230, and the first inorganic layer 330 is on the first organic layer 320. However, the present inventive concept is not limited thereto, and an additional organic layer or an additional inorganic layer may also be included in other embodiments.

The first organic layer 320 may be formed of an organic material, and may include at least one material selected from the group consisting of an acrylic resin, a methacrylic resin, polyisoprene, a vinyl-based resin, an epoxy-based resin, an urethane-based resin, a cellulose-based resin, and/or a perylene-based resin. In detail: examples of the acrylic resin are butyl acrylate and ethyl hexyl acrylate; examples of the methacrylic resin include propylene glycol methacrylate and tetrahydrofurfuryl methacrylate; examples of the vinyl-based resin include vinyl acetate and N-vinyl pyrrolidone; examples of the epoxy-based resin include cycloaliphatic epoxide, epoxy acrylate, and vinyl epoxy-based resin; examples of the urethane-based resin include urethane acrylate; and examples of the cellulose-based resin include cellulose nitrate, but the examples are not limited thereto.

The first inorganic layer 330 may be formed of an inorganic material, and may include at least one material selected from the group consisting of a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, and/or a silicon oxynitride (SiON).

A first material 332 that is different from the first organic layer 320 of the first encapsulation unit 300 may be used to fill the first through portion 300a. The first organic layer 320 may be formed of organic materials as those described above, and thus, the first material 332 filling in the first through portion 300a may include an inorganic material instead of an organic material. The first material 332 may be the same as the material for forming the first inorganic layer 330. For example, when the first inorganic layer 330 is on the first organic layer 320, and is an uppermost layer of the first encapsulation unit 300, as illustrated in FIG. 2, the first material 332 filling in the first through portion 300a may be the same as the material of the first inorganic layer 330. In the present embodiment, the first inorganic layer 330 and the first through portion 300a may be formed as a single unit.

According to another exemplary embodiment, the first material 332 filling in the first through portion 300a may include a metal, which may be a metal having excellent ductility. Ductility refers to a property of metal where the metal is not destroyed by tension equal to or greater than an elastic limit, but is instead plastically deformed. Ductility of a metal may be defined by an elongation, which may be expressed as (ΔL)/(L₀)*100(%), where L₀ denotes an original length of the metal, L denotes a length of the metal that is elongated when being pulled by two ends, and AL denotes a difference between the original length L₀ and the elongated length L. A metal having high elongation may be used as the first material 332 according to the present exemplary embodiment, and the elongation of the metal may be 5% or higher.

The first through portion 300a may be formed through the first encapsulation unit 300 as described above, so that at least a portion of an upper surface of the opposite electrode 230 located under the first encapsulation unit 300 is initially exposed. In the present embodiment, the opposite electrode 230 is not exposed to the outside through the first through portion 300a because the first material 332 fills in the first through portion 300a.

The first through portion 300a may be formed over the entire surface of the flexible substrate 100 (e.g., at intervals), and when a portion of the flexible substrate 100 is bent, the first through portion 300a may be formed at a bending area BA, as illustrated in FIG. 6. That is, when the flexible substrate 100 is bent at an angle, the flexible substrate 100 has the bending area BA, and a flat area FA adjacent the bending area BA, and the first through portion 300a may be formed at the bending area BA.

The flexible display apparatus may have a curved structure having a given curvature radius. To design a flexible display apparatus having various curvature radii, a limit curvature radius, at which cracks of a display panel may be generated, is sought to be reduced or minimized. For example, when bending a display panel to or past a corresponding limit curvature radius, a greatest amount of tensile stress may be applied to an encapsulation unit, which is at an upper layer of the display apparatus, and the generated cracks may begin at an inorganic layer, which is vulnerable to stress. Accordingly, moisture, oxygen, or the like may flow into the display panel through the encapsulation unit where the cracks are generated, thereby causing defects in the display panel. In particular, when the inorganic layer of the encapsulation unit has a single layer structure, and is formed over the entire surface of the display panel, the inorganic layer has a structure that is even more vulnerable to stress.

Thus, according to the flexible display apparatus of an exemplary embodiment, the first through portion 300a in the first encapsulation unit 300 is configured to distribute stress applied to the display panel. Thus, the first through portion 300a in the first encapsulation unit 300 may distribute stress applied to the entire surface of the inorganic layer 330 of the first encapsulation unit 300, thereby reducing a limit curvature radius of the display panel. Also, because the first through portion 300a is located in the first encapsulation unit 300, which is located in a proceeding direction of light, anomalous refraction of light occurs, thereby improving a viewing angle of the display apparatus.

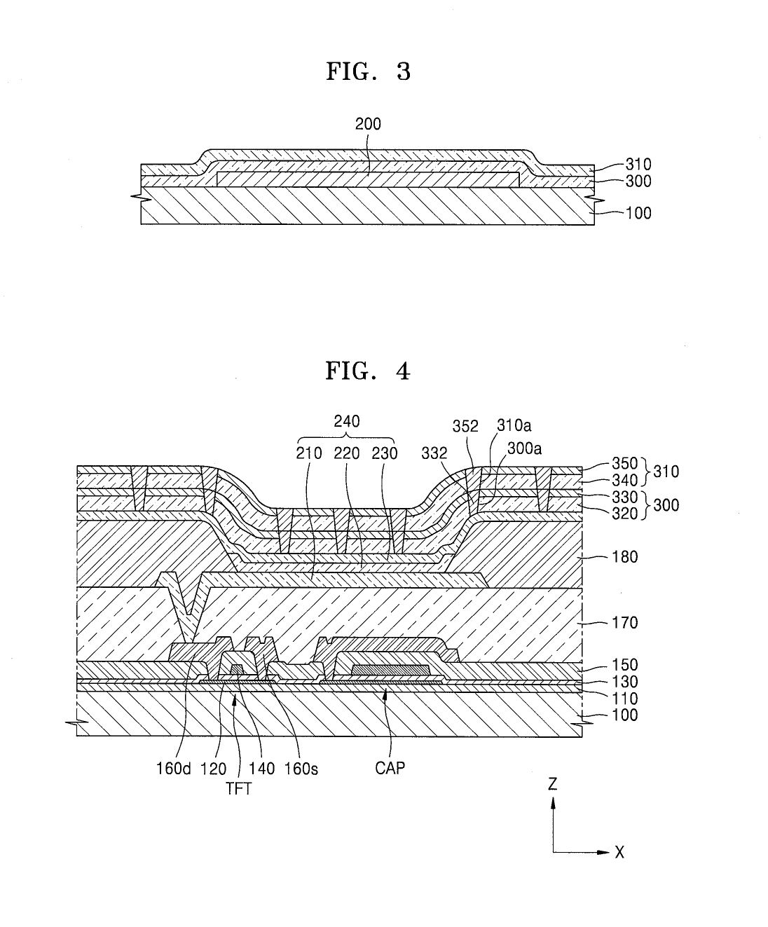

FIGS. 3 through 5 are schematic cross-sectional views illustrating a flexible display apparatus according to another exemplary embodiment of the inventive concept.

Referring to FIG. 3, the flexible display apparatus according to another exemplary embodiment of the inventive concept includes a flexible substrate 100, a display unit 200 on the flexible substrate 100, a first encapsulation unit 300 covering the display unit 200, a second encapsulation unit 310, and a first through portion 300a and a second through portion 310a respectively passing through the first encapsulation unit 300 and the second encapsulation unit 310. That is, according to the exemplary embodiments shown in FIGS. 3, 4, and 5, the second encapsulation unit 310 is additionally formed on the first encapsulation unit 300 of the flexible display apparatus of the previous exemplary embodiment.

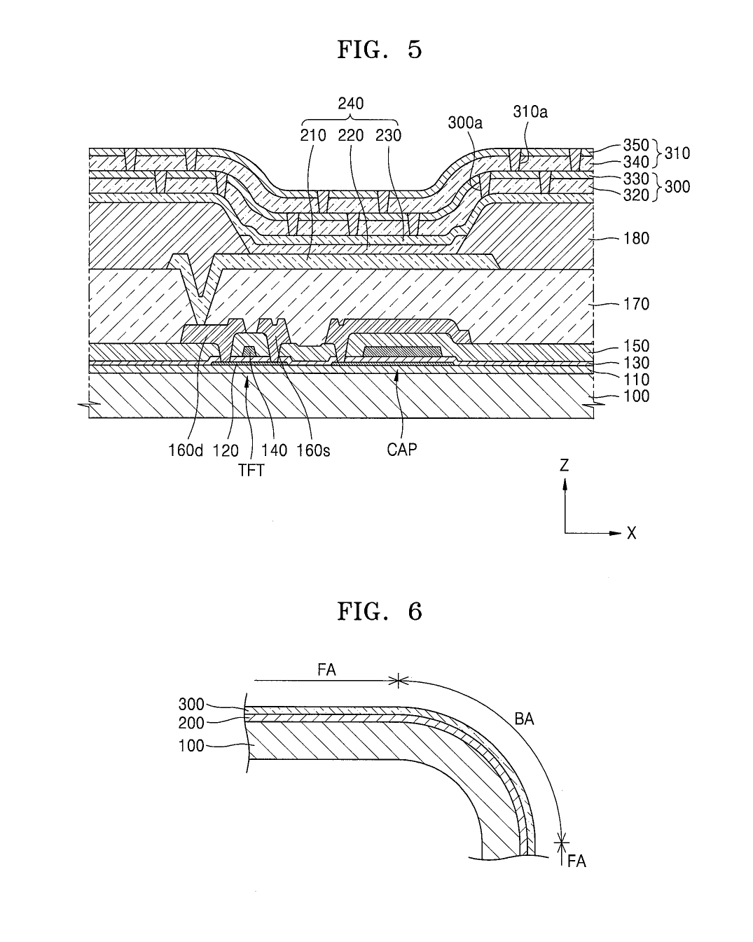

According to the exemplary embodiment illustrated in FIG. 4, the first through portion 300a and the second through portion 310a respectively overlap, and according to the exemplary embodiment illustrated in FIG. 5, the first through portion 300a and the second through portion 310a are located at different positions and do not overlap. The flexible substrate 100 and the display unit 200 according to the present exemplary embodiments are the same as those of the previous embodiment, and thus, descriptions thereof provided above apply here.

The flexible display apparatus according to the present exemplary embodiments further includes the second encapsulation unit 310 on the first encapsulation unit 300 described with respect to the previous embodiment. As illustrated in FIGS. 3 and 4, the first encapsulation unit 300 according to the present exemplary embodiment may include the first organic layer 320 and the first inorganic layer 330, and the second encapsulation unit 310 may include a second organic layer 340 and a second inorganic layer 350.

The first organic layer 320 and the second organic layer 340 may be formed of materials that are independent of each other, and may be formed of organic materials including, for example, at least one material selected from the group consisting of an acrylic resin, a methacrylic resin, polyisoprene, a vinyl-based resin, an epoxy-based resin, an urethane-based resin, a cellulose-based resin, and/or a perylene-based resin. The organic materials included in the first organic layer 320 and the second organic layer 340 may be the same as one another, or may be different from one another.

Inorganic materials for forming the first inorganic layer 330 and the second inorganic layer 350 may be independent of each other, and may include, for example, at least one material selected from the group consisting of a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, and/or a silicon oxynitride (SiON). Inorganic materials for forming the first inorganic layer 330 and the second inorganic layer 350 may be the same as or different from each other.

As illustrated in FIG. 4, at least one first through portion 300a may be formed through the first encapsulation unit 300, and at least one second through portion 310a may be formed through the second encapsulation unit 310. The first material 332 that is different from the first organic layer 320 of the first encapsulation unit 300 may fill in the first through portion 300a, and also, a second material 352 that is different from the second organic layer 340 of the second encapsulation unit 310 may fill in the second through portion 310a. As such, the first material 332 and the second material 352 respectively filling in the first through portion 300a and the second through portion 310a may include an inorganic material. The first material 332 may be the same a material for forming the first inorganic layer 330, and the second material 352 may be the same as a material for forming the second inorganic layer 350. Further, the first material 332 and the second material 352 may be identical materials.

For example, when the first material 332 is the same as the material for forming the first inorganic layer 330, the first material 332 filling in the first through portion 300a may be formed at the same time as the first inorganic layer 330. Also, when the second material 352 is the same as the material for forming the second inorganic layer 350, the second material 352 filling in the second through portion 310a may be formed at the same time as the second inorganic layer 350.

According to embodiments, the first material 332 filling in the first through portion 300a, and the second material 352 filling in the second through portion 310a may be identical materials, and in this case, the first through portion 300a and the second through portion 310a may fill in the through portions 300a and 310a at the same time. Further, when the first material 332 and the second material 352 are the same as the material of the second inorganic layer 350, the second inorganic layer 350, the first material 332, and the second material 352 may be formed as a single unit.

According to another exemplary embodiment, the materials 332 and 352 filling in the first through portion 300a and the second through portion 310a may include a metal that may have excellent ductility. The metal according to the present exemplary embodiment may be a metal having a high elongation of about 5% or higher.

The first through portion 300a and the second through portion 310a may be formed to pass through the first encapsulation unit 300 and the second encapsulation unit 310, respectively, as described above. Accordingly, at least a portion of the upper surface of the opposite electrode 230 located under the first encapsulation unit 300 is initially exposed by the first and second through portions 300a and 310a until an inorganic material or a metal fills in the first through portion 300a and the second through portion 310a.

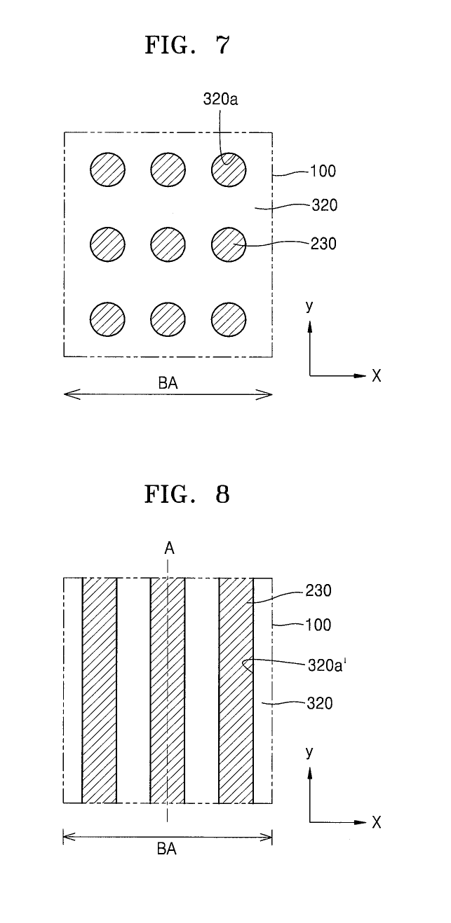

The first through portion 300a and the second through portion 310a may be formed over the entire surface of the flexible substrate 100, or may be formed in the bending area BA of the flexible substrate 100. That is, when the flexible substrate 100 is bent at an angle, as illustrated in FIGS. 6 and 7, the flexible substrate 100 has the bending area BA, and a flat area FA next to the bending area BA. The first through portion 300a and the second through portion 310a may be formed in the bending area BA.

The flexible display apparatus may have a curved structure having a curvature radius. To design a flexible display apparatus having various curvature radii, a limit curvature radius, at which cracks of a display panel may be generated, is sought to be reduced or minimized. For example, when bending a display panel up to or beyond a limit curvature radius of the display panel, the greatest degree of tensile stress may be applied to an encapsulation unit, which is at an upper layer portion, and cracks may be generated starting at an inorganic layer, which is vulnerable to stress. Then moisture, oxygen, or the like may flow into the display panel through the encapsulation unit where the cracks are generated, thereby causing defects in the display panel. In particular, when the inorganic layer of the encapsulation unit has a single layer structure, and is formed over the entire surface of the display panel, the structure of the inorganic layer is even more vulnerable to stress.

Thus, according to the flexible display apparatus of an exemplary embodiment, the first through portion 300a through the first encapsulation unit 300, and the second through portion 310a through the second encapsulation unit 310, may be formed to distribute stress applied to the display panel by bending. Thus, the first through portion 300a and the second through portion 310a may distribute stress applied to the entire surface of the inorganic layer of the first encapsulation unit 300, thereby reducing a limit curvature radius of the display panel. Also, as the first through portion 300a and the second through portion 310a are respectively located in the first encapsulation unit 300 and the second encapsulation unit 310, which are located in a proceeding direction of light emitted by the pixels, anomalous refraction of light is induced to thereby improve a viewing angle of the display apparatus.

FIG. 6 is a schematic cross-sectional view illustrating a bending area and a flat area of a flexible display apparatus according to an exemplary embodiment of the inventive concept, FIG. 7 is a schematic plan view illustrating an organic layer included in an encapsulation unit of a flexible display apparatus according to an exemplary embodiment of the inventive concept, and FIG. 8 is a schematic plan view illustrating an organic layer included in an encapsulation unit of a flexible display apparatus according to an exemplary embodiment of the inventive concept.

Referring to FIGS. 6 and 7, the first through portion 300a may have a circular cross-section. However, the present inventive concept is not limited thereto, and the first through portion 300a may have an oval cross-section, or may have a mesh-shaped cross-section. The opposite electrode 230 under the first organic layer 320 may be exposed through a through portion 320a formed in the first organic layer 320.

Referring to FIG. 8, according to another exemplary embodiment, a through portion 320a′ may have a linear cross-section. In particular, when the through portion 320a′ has a linear cross-section, a portion where the through portion 320a′ is formed may be the bending area BA of the flexible substrate 100. That is, the through portion 320a′ may extend along a bending axis direction (e.g., a Y direction) corresponding to a bending axis A along which the flexible substrate 100 is configured to be bent, and flexibility of a flexible display panel bent with respect to the through portion 320a′ may be improved, as the through portion 320a′ formed in the first encapsulation unit 300 is configured to distribute stress otherwise applied to the first inorganic layer 330 of the first encapsulation unit 300.

According to another exemplary embodiment, a third inorganic layer may be further interposed between the display unit 200 and the first encapsulation unit 300. That is, the third inorganic layer may be interposed between the opposite electrode 230 of the display unit 200 and the first organic layer 320 of the first encapsulation unit 300. The third inorganic layer may further prevent foreign substances from penetrating through the first encapsulation unit 300 into the organic light-emitting device due to formation of the first through portion 300a, and may prevent a short circuit between the opposite electrode 230 and a metal of the first material 332 filling in the first through portion 300a (when the first material 332 is formed of a metal).

While description is focused on the flexible display apparatus above, the inventive concept is not limited thereto. For example, a method of manufacturing the flexible display apparatus as described above is also in the scope of the present inventive concept. A method of manufacturing the flexible display apparatus will be described with reference to FIGS. 1 and 2.

According to the present exemplary embodiment, first, the display unit 200 may be formed on the flexible substrate 100. The display unit 200 is the same as described above, and thus, descriptions thereof provided above apply here. Next, the first encapsulation unit 300 may be formed by sequentially stacking the first organic layer 320 and the first inorganic layer 330 on the display unit 200 to cover the display unit 200.

After forming the first encapsulation unit 300, the first through portion 300a passing through the first encapsulation unit 300 may be formed. The first through portion 300a may be formed using various methods. For example, after forming the first encapsulation unit 300 including the first organic layer 320 and the first inorganic layer 330, the first through portion 300a through the first organic layer 320 and through the first inorganic layer 330 may be formed. In this case, the first through portion 300a may be formed by using an etching solution capable of simultaneously etching the first organic layer 320 and the first inorganic layer 330.

According to another exemplary embodiment, the first through portion 300a may be formed using a patterned mask. That is, a patterned mask may be used in an operation of forming the first organic layer 320, and may be used in an operation of forming the first inorganic layer 330, thereby forming the first organic layer 320 having a first hole 320a, and the first inorganic layer 330 having a second hole 330a (see FIG. 1). In the present embodiment, the first hole 320a and the second hole 330a may be formed to overlap so as to collectively form the first through portion 300a that passes through the first encapsulation unit 300.

A material that is different from the first organic layer 320 may fill in the first through portion 300a. For example, the first through portion 300a may include therein the same material as the first inorganic layer 330, and when the first inorganic layer 330 is on the first organic layer 320, a material filling the first through portion 300a is the same as the material of the first inorganic layer 330, and may be formed with the first organic layer 330 as a single unit.

According to another exemplary embodiment, a material filling in the first through portion 300a may be a metal. The metal filling in the first through portion 300a may be a metal having excellent ductility. The metal according to the present exemplary embodiment may be a metal having a high elongation which may be about 5% or higher.

The flexible display apparatus may have a curved structure having a given curvature radius. To design a flexible display apparatus capable of various curvature radii, a limit curvature radius at which cracks of a display panel may be generated is to be reduced or minimized. For example, when bending a display panel up to or beyond a limit curvature radius, a greatest degree of tensile stress may be applied to an encapsulation unit at an upper layer portion, and cracks may begin at an inorganic layer that is vulnerable to stress. Then moisture or oxygen or the like may flow into the display panel through the cracks in the encapsulation unit, thereby potentially causing defects in the display panel. In particular, when the inorganic layer of the encapsulation unit has a single layer structure and is formed over the entire surface of the display panel, the structure of the inorganic layer is even more vulnerable to stress.

Thus, according to the flexible display apparatus of an exemplary embodiment, as the first through portion 300a passing through the first encapsulation unit 300 is formed, stress applied to the display panel may be distributed. Thus, the first through portion 300a formed in the first encapsulation unit 300 may distribute stress applied to the entire surface of the inorganic layer 330 of the first encapsulation unit 300, thereby reducing a limit curvature radius of the display panel. Also, because the first through portion 300a is located in the first encapsulation unit 300, which is located in a proceeding direction of light emitted by the display unit 200, anomalous refraction of light is induced to thereby improve a viewing angle. While the method of manufacturing the flexible display apparatus including the first through portion 300a is described above, the flexible display apparatus according to the another exemplary embodiment, in which the second encapsulation unit 310 is further included on the first encapsulation unit 300, may also be formed in the same manner.

According to one or more embodiments of the inventive concept, a flexible display apparatus having improved flexibility, and a method of manufacturing the flexible display apparatus may be implemented. However, the scope of the present inventive concept is not limited by the effects.

It should be understood that exemplary embodiments described herein should be considered in a descriptive sense only and not for purposes of limitation. Descriptions of features or aspects within each exemplary embodiment should typically be considered as available for other similar features or aspects in other exemplary embodiments.

While one or more exemplary embodiments have been described with reference to the figures, it will be understood by those of ordinary skill in the art that various changes in form and details may be made therein without departing from the spirit and scope as defined by the following claims and their equivalents.

What is claimed is:

1. A flexible display apparatus comprising:
a flexible substrate;
a display unit on the flexible substrate;
a first encapsulation unit covering the display unit, defining a first through portion therethrough, and comprising:
a first organic layer; and
a first inorganic layer on the first organic layer; and
a first material in the first through portion that is different from a material of the first organic layer.

2. The flexible display apparatus of claim 1, wherein the first inorganic layer comprises a material that is the same as the first material.

3. The flexible display apparatus of claim 1, wherein the first material comprises a metal having an elongation of about 5% or higher.

4. The flexible display apparatus of claim 1, wherein the display unit comprises:
a thin film transistor; and
an organic light-emitting device comprising:
a pixel electrode electrically connected to the thin film transistor;
an intermediate layer comprising an emission layer on the pixel electrode; and
an opposite electrode on the intermediate layer and facing the pixel electrode,
wherein the first material contacts the opposite electrode.

5. The flexible display apparatus of claim 1, wherein the flexible substrate has a bending area at which the flexible substrate is configured to be bent, and a flat area adjacent the bending area, and
wherein the first through portion is at the bending area.

6. The flexible display apparatus of claim 5, wherein the first through portion extends along a bending axis direction of the bending area.

7. The flexible display apparatus of claim 1, further comprising:
a second encapsulation unit on the first encapsulation unit, defining a second through portion therethrough, and comprising:
a second organic layer; and
a second inorganic layer on the second organic layer; and
a second material in the second through portion that is different from a material of the second organic layer.

8. The flexible display apparatus of claim 7, wherein the second inorganic layer comprises a material that is the same as the second material.

9. The flexible display apparatus of claim 7, wherein the second material comprises a metal having an elongation of about 5% or higher.

10. The flexible display apparatus of claim 9, wherein the first material comprises a first metal, and
wherein the second material comprises a second metal having a higher elongation than that of the first metal.

11. The flexible display apparatus of claim 7, wherein the second material contacts the first inorganic layer.

12. The flexible display apparatus of claim 7, wherein the flexible substrate has a bending area at which the flexible substrate is configured to be bent, and a flat area adjacent the bending area, and
wherein the first through portion and the second through portion are at the bending area.

13. The flexible display apparatus of claim 12, wherein the first through portion and the second through portion extend along a bending axis direction of the bending area.

14. The flexible display apparatus of claim 1, further comprising a third inorganic layer between the display unit and the first encapsulation unit,
wherein the first material contacts the third inorganic layer.

15. A method of manufacturing a flexible display apparatus, the method comprising:
forming a display unit on a flexible substrate;
forming a first encapsulation unit covering the display unit by forming a first organic layer on the display unit, and forming a first inorganic layer on the first organic layer;
forming a first through portion through the first encapsulation unit; and
filling a first material in the first through portion,
wherein the first organic layer comprises a material that is different from the first material.

16. The method of claim 15, wherein the first material comprises:
a same material as the first inorganic layer; or
a metal having an elongation of about 5% or higher.

17. The method of claim 15, wherein the forming of the first through portion comprises etching a portion of the first encapsulation unit.

18. The method of claim 15, wherein the forming of a first through portion comprises using a patterned mask.
